(19) United States
(12) Patent Application Publication
(10) Pub. No.: US 2013/0289892 A1
(43) Pub. Date: Oct. 31, 2013

(54) Time-of-Flight Mass Spectrometer and Data Compression Method Therefor

(71) Applicant: JEOL LTD., Tokyo (JP)

(72) Inventor: Takaya Satoh, Tokyo (JP)

(73) Assignee: JEOL LTD., Tokyo (JP)

(21) Appl. No.: 13/792,413

(22) Filed: Mar. 11, 2013

(30) Foreign Application Priority Data
Apr. 25, 2012 (JP) 2012-099645

(51) Int. Cl. H01J 49/00; H03M 7/30; H01J 49/40

(52) U.S. Cl. CPC H01J 49/0036; H01J 49/40; H03M 7/30
USPC 702/23; 250/287

(57) ABSTRACT

A data compression method for use by a flight-of-time mass spectrometer reduces the amount of digital data, which are converted from mass spectra by a digitizer, by thinning out their data points without reducing the amount of information over the whole range. The mass spectrometer has a data processing unit including data reduction means which reduces the number of data points of digital data delivered from the digitizer in response to an electrical signal indicative of ions based on a previously entered data table such that m/z regions partitioned by given flight times or given ink are set to have different numbers of data points.

### BACKGROUND OF THE INVENTION

1. Field of the Invention

The present invention relates to a data processing method used for a time-of-flight mass spectrometer that is used in quantitative analysis and simultaneous qualitative analysis of trace compounds and also in structural analysis of sample ions.

2. Description of Related Art

### Time-of-Flight Mass Spectrometer (TOFMS)

A time-of-flight (TOF) mass spectrometer is an instrument that finds the mass-to-charge ratio (m/z) of each ion by accelerating ions with a given amount of energy, causing them to travel, and calculating the mass-to-charge ratio from the time taken for each ion to reach a detector. In the TOFMS, ions are accelerated with a given pulsed voltage Vₐ. At this time, from the law of conservation of energy, the velocity v of each ion is given by

$$\begin{matrix}\frac{{mv}^{2}}{2} = {qeV}_{a} & ( 1 ) \\ v = \sqrt{\frac{2 {qeV}_{a}}{m}} & ( 2 )\end{matrix}$$

where m is the mass of the ion, q is the electric charge of the ion, and e is the elementary charge.

Therefore, the flight time T required for the ion to reach a detector, placed behind at a given distance of L, is given by

$$T = \frac{L}{v} = L \sqrt{\frac{m}{2 {qeV}_{a}}} \qquad ( 3 )$$

As can be seen from Eq. (3), ions can be separated by employing the fact that the flight time T differs according to the mass m of each ion. TOFMS is an instrument employing this principle. One example of linear TOFMS is shown in FIG. 1. Furthermore, reflectron TOFMS that permits improvement of energy convergence and extension of the flight distance by placing a reflectron field between the ion source and the detector has had wide acceptance. One example of reflectron TOFMS is shown in FIG. 2.

### Helical Orbit TOFMS

The mass resolution of a TOF mass spectrometer is defined as follows:

$$mass resolution = \frac{T}{2 Δ T} \qquad ( 4 )$$

where T is the total flight time and ΔT is a peak width. That is, if the total flight time T can be lengthened while maintaining constant the peak width ΔT, then the mass resolution can be improved. However, in the related art linear or reflectron type TOFMS, increasing the total flight time T (i.e., increasing the total flight distance) will lead directly to an increase in instrumental size. A multi-pass time-of-flight mass spectrometer has been developed to realize high mass resolution while avoiding an increase in instrumental size (see M. Toyoda, D. Okumura, M. Ishihara and I. Katakuse, J. Mass Spectrom., 2003, 38, pp. 1125-1142). This instrument uses four toroidal electric fields each consisting of a combination of a cylindrical electric field and a Matsuda plate. The total flight time T can be lengthened by accomplishing multiple turns in an 8-shaped circulating orbit. In this apparatus, the spatial and temporal spread at the detection surface has been successfully converged up to the first-order term using the initial position, initial angle, and initial kinetic energy.

However, the TOFMS in which ions revolve many times in a closed trajectory suffers from the problem of overtaking. That is, because ions revolve multiple times in a closed trajectory, lighter ions moving at higher speeds overtake heavier ions moving at smaller speeds. Consequently, the fundamental concept of TOFMS that ions arrive at the detection surface in turn first from the lightest one does not hold.

The spiral-trajectory TOFMS has been devised to solve this problem. The spiral-trajectory TOFMS is characterized in that the starting and ending points of a closed trajectory are shifted vertically from the closed trajectory plane. To achieve this, in one method, ions are made to impinge obliquely from the beginning (see JP-A-2000-243345). In another method, the starting and ending points of the closed trajectory are shifted vertically using a deflector (see JP-A-2003-86129). In a further method, laminated toroidal electric fields are used (see JPA-2006-12782).

Another TOFMS has been devised which is based on a similar concept but in which the trajectory of the multiple-reflection TOF-MS (see GB2080021) where overtaking occurs is zigzagged (see WO2005/001878 pamphlet).

Method of Acquiring Data from TOFMS

Mass spectra derived from TOFMS are created using a digitizer that digitizes electrical signals delivered from detectors. In recent years, with the development of high-speed digital circuit technology, sampling at 1 to 4 GHz is prevalent in methods for obtaining data from TOFMS so as to achieve high resolution. That is, each electrical signal (i.e., ion intensity) is sampled at regular time intervals of 0.25 to 1 ns. The time axis of the obtained data string at regular intervals of time is converted into the m/z axis using a calibration formula. It is often that the calibration formula is a polynomial equation derived based on Eq. (3) and given by

\sqrt{(m/z)}=a+bT+cT²+dT³+ (5)

where a, b, c, are d are constants.

As the ion flight time elongates or the resolution of the TOF mass spectrometer increases due to increases in rate of sampling data using a digitizer, the number of digital data points contained in a mass spectrum increases immensely. Furthermore, coupling of TOFMS with a liquid chromatography technique such as liquid chromatography TOFMS or gas chromatography TOFMS and development of applied fields such as imaging mass spectroscopy for collecting a mass spectrum for each set of positional information while using a MALDI or SIMS ion source as an ion source lead to increases in the amount of data.

However, the density of data points obtained at regular intervals of time does not always match the amount of information. If the mass resolution is constant, the half-value width of each peak is in proportion to the flight time of each ion, i.e., the square root of the mass of the ion, as seen from Eq. (4). In the conventional method, data is sampled at regular intervals of time and so the number of data points included in each peak is also in proportion to the square root of the mass of the ion.

On the other hand, as the mass is increased, the amount of information contained per unit mass generally decreases. Therefore, in a high mass range, the number of data points can be fewer for the following reasons.

First, in the case of a time-of-flight mass spectrometer, time aberrations in the ion optics increase and the peak width ΔT increase and, therefore, the mass resolution tends to decrease after m/z 3000 has been reached.

Secondly, in a region of small m/z values, the mass spectrum is complicated because foreign substances and matrix-derived isotope peaks in the sample increase. This necessitates high mass resolution.

FIG. 3A is a mass spectrum of a mixture sample obtained by mixing three samples of polypropylene glycol having average molecular amounts of 1,000, 2,000, and 4,000, respectively. The total number of data points of this mass spectrum is 723,776.

FIGS. 3B, 3C, and 3D are enlarged views of vicinities of m/z values of 656, 1,714, and 3,343, respectively. In FIG. 3B, isotope peaks (B) originated from other compounds are observed, as well as isotope peaks (A) originated from a main compound and spaced apart by 1 u. However, as ion mass increases, peaks spaced apart by 1 u are prevalent as shown in FIGS. 3C and 3D.

As described so far, in a flight-of-time mass spectrometer, data is sampled at regular intervals of time and, therefore, if a sufficiently large number of data points are secured on a mass spectrum for a low mass region where high mass resolution is required, then there are an excessively large number of data points in a high mass region. This will lead to an excessive amount of data.

### SUMMARY OF THE INVENTION

In view of the foregoing, it is an object of the present invention to reduce the amount of data by thinning out data points of digital data converted from a mass spectrum using a digitizer without reducing the amount of information over the whole region of the spectrum.

This object is achieved by a TOF (time-of-flight) mass spectrometer associated with the present invention, the spectrometer having an ion source for ionizing a sample, a time-of-flight (TOF) mass analyzer for causing generated ions to travel and mass-separating the ions according to their mass-to-charge ratio, a detector for detecting the ions mass-separated by the mass analyzer according to their mass-to-charge ratio and outputting an electrical signal, a digitizer for converting the electrical signal outputted from the detector into digital form, and a processing unit to which digital data from the digitizer is supplied. The processing unit has (1) data compression means for reducing the number of data points of the digital data such that m/z regions partitioned by given flight times or given m/z are set to have different numbers of data points and (2) storage means in which the digital data whose number of data points has been reduced by the data compression means are stored.

In one feature of this mass spectrometer, the data compression means reduces the number of data points by taking an average of flight times, m/z values, or ion intensity values between preset numbers of data points.

In another feature of this mass spectrometer, the number of data points of the digital data that is set to different values for the m/z regions partitioned by the given flight times or given m/z is set to larger values with increasing m/z value of measured ion peak.

In a further feature of this mass spectrometer, the number of data points of the digital data that is set to different values for the m/z regions partitioned by the given flight times or given m/z is set to a smaller value for a preset m/z region as compared with its adjacent m/z regions.

In an additional feature of this mass spectrometer, a liquid chromatograph or gas chromatograph is coupled to the ion source. The number of data points of digital data obtained by measuring the sample isolated chromatographically is reduced.

In a still other feature of this mass spectrometer, the ion source is a MALDI or SIMS ion source, and the number of data points obtained using imaging mass spectrometry is reduced.

The present invention also provides a data compression method for use by a time-of-flight mass spectrometer producing a mass spectrum including a greatly increased number of digital data points. The data compression method starts with (1) reducing the number of data points of the digital data such that m/z regions partitioned by given flight times or given m/z are set to have different numbers of data points. (2) Then, the digital data whose number of data points has been reduced by the step (1) are stored.

In one feature of the step (1) of this data compression method, the number of the data points is reduced by taking an average of flight times, m/z values, or ion intensity values between preset numbers of data points.

In another feature of the step (1), the m/z regions partitioned by the given flight times or given m/z are set to have different numbers of data points such that the number of data points in any one m/z region increases with increasing m/z value of measured ion peak.

In a further feature of the step (1), the number of data points of the digital data that is set to different values for the m/z regions partitioned by the given flight times or given m/z is set to a smaller value for a preset m/z region as compared with its adjacent m/z regions.

In an additional feature of this data compression method, a chromatograph is coupled to the TOF mass spectrometer. The number of data points of digital data obtained by measuring the sample isolated chromatographically is reduced.

In a yet other feature of this data compression method, the TOF mass spectrometer uses a MALDI or SIMS ion source, and the number of data points obtained using imaging mass spectrometry is reduced.

The TOF mass spectrometer according to the present invention has: an ion source for ionizing a sample, a time-of-flight (TOF) mass analyzer for causing generated ions to travel and mass-separating the ions according to their mass-to-charge ratio, a detector for detecting the ions mass-separated by the mass analyzer according to their mass-to-charge ratio and outputting an electrical signal, a digitizer for converting the electrical signal outputted from the detector into digital form, and a processing unit to which digital data from the digitizer is supplied. The processing unit has (1) data compression means for reducing the number of data points of the digital data such that m/z regions partitioned by given flight times or given m/z are set to have different numbers of data points and (2) storage means in which the digital data whose number of data points has been reduced by the data compression means are stored. Therefore, the amount of data can be reduced by thinning out the data points of a mass spectrum consisting of digital data converted by the digitizer without reducing the amount of information over the whole range of the spectrum.

The data compression method according to the present invention comprises the steps of: (1) reducing the number of data points of the digital data such that m/z regions partitioned by given flight times or given m/z are set to have different numbers of data points; and then (2) storing the digital data whose number of data points has been reduced by the step (1). Therefore, the amount of data can be reduced by thinning out data points of a mass spectrum consisting of digital data converted by a digitizer without reducing the amount of information over the whole range of the spectrum.

### BRIEF DESCRIPTION OF THE DRAWINGS

FIG. 1 is a diagram showing one conventional TOF-MS instrument.

FIG. 2 is a diagram showing another conventional TOF-MS instrument.

FIGS. 3A-3D show some sets of spectral data obtained using a conventional TOF-MS instrument.

FIG. 4 is a block diagram of a TOF-MS instrument associated with the present invention.

FIG. 5 is a table illustrating one example of method of setting data into the TOF-MS instrument shown in FIG. 4.

FIGS. 6A-6C show some sets of mass spectral data obtained using the TOF-MS instrument shown in FIG. 4.

FIG. 7 is a table showing another method of setting data into a TOF-MS instrument associated with the present invention.

FIG. 8 is a diagram showing a MALDI mass spectrometer according to the present invention

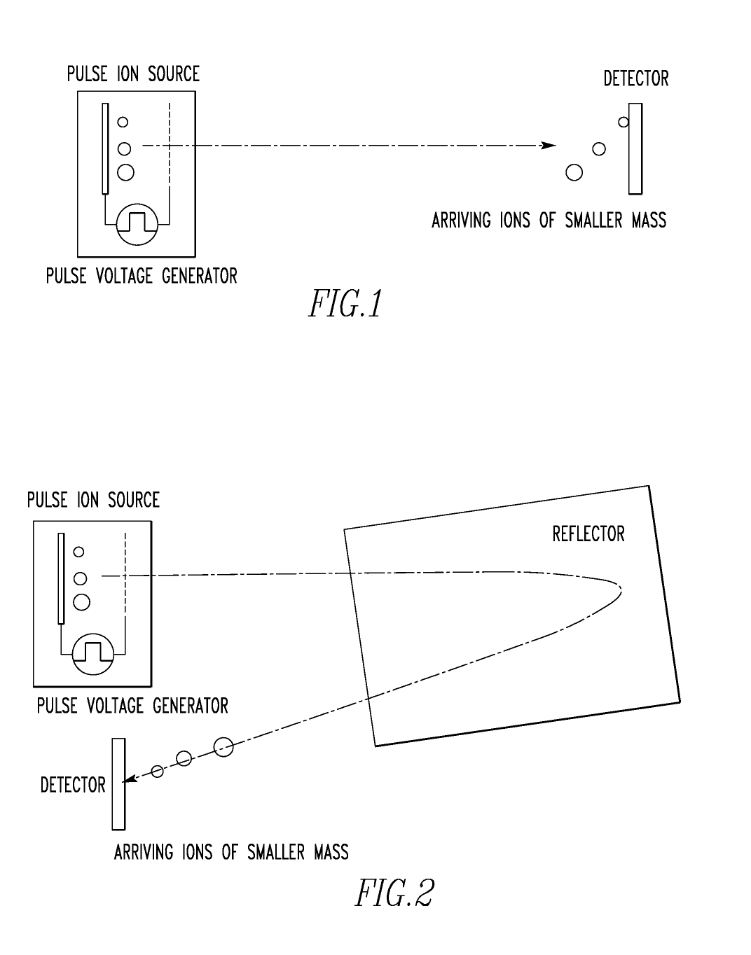

### DESCRIPTION OF THE PREFERRED EMBODIMENTS

The preferred embodiments of the present invention are hereinafter described with reference with the drawings.

### Embodiment 1

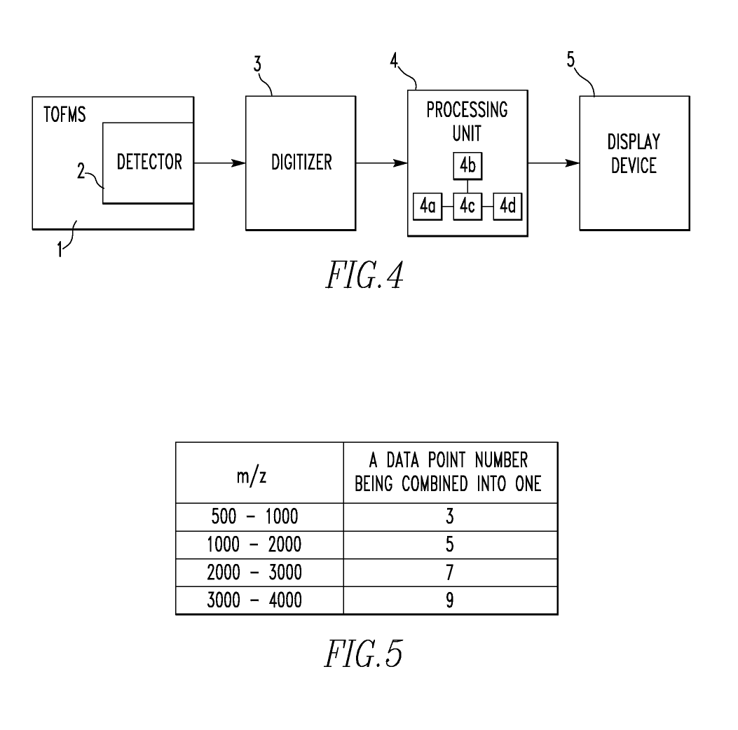

FIG. 4 shows the fundamental structure of a time-of-flight (TOF) mass spectrometer according to the present invention. The spectrometer, indicated by reference numeral 1, includes a microchannel plate (MCP) detector 2 on which ions impinge at different flight times while reflecting different mass-to-charge ratios of the ions.

The output signal from the MCP detector 2 indicating ion peaks is converted into digital form by a digitizer 3 and sent to a processing unit 4 as consisting of a microcomputer. The ion-peak signal processed by the processing unit 4 is converted into m/z values, arrayed on the horizontal axis, and displayed as a mass spectrum on a display device 5 such as a liquid crystal display.

In this structure, the electrical signal from the detector 2 incorporated in the TOF mass spectrometer 1 is converted into digital data at regular intervals of time by the digitizer 3. The processing unit 4 receiving the digital data performs data compression such that plural adjacent data points are combined into one data point in each m/z region in order to reduce the amount of data.

The processing unit 4 has a memory 4a such as a DRAM for temporarily storing the digital data delivered from the digitizer 3. The digital data in the memory 4a is compressed by a processor 4c included in the processing unit 4 based on the content of an instruction entered from the input portion 4b of the processing unit 4. The compressed data is transferred from the memory 4a via the processor 4c to a mass storage unit 4d such as a hard disk, where the data is stored over a long term.

The values of flight times forming boundaries of m/z values are calculated using the calibration formula (5) set forth above. The compression ratio in a region that is partitioned by some boundaries, i.e., the number of data points combined in one, is entered in a table by previously specifying values (see FIG. 5).

When plural data points are combined into one, average values of flight time values and ion intensity values may be calculated and adopted. The flight time values of the obtained data points are converted into m/z values using calibration coefficients and displayed on the display device.

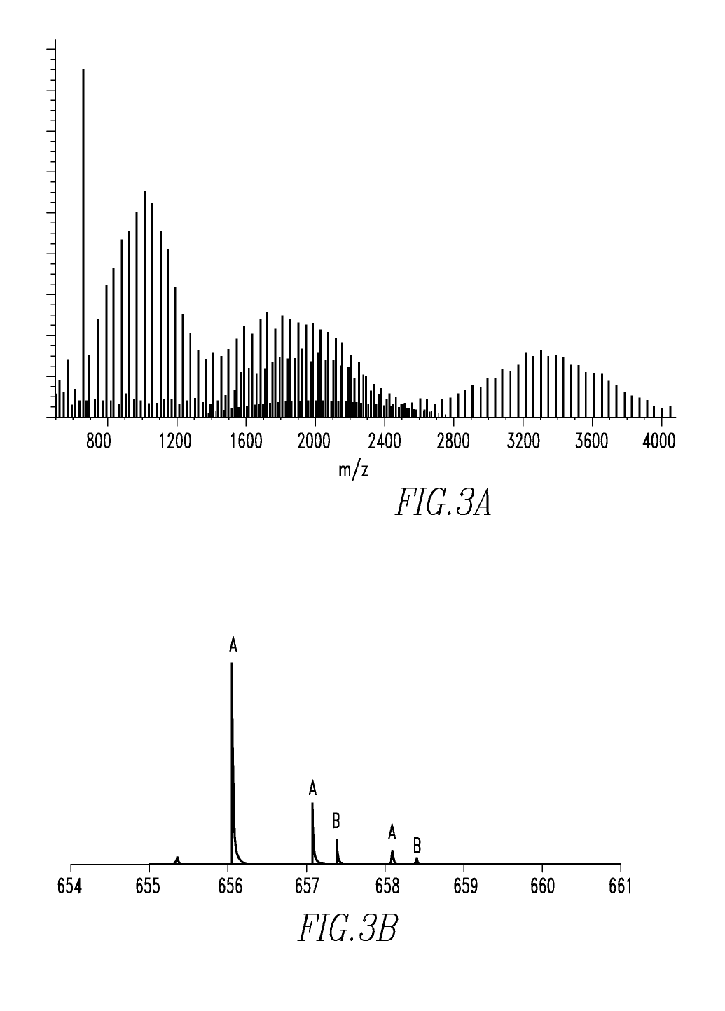

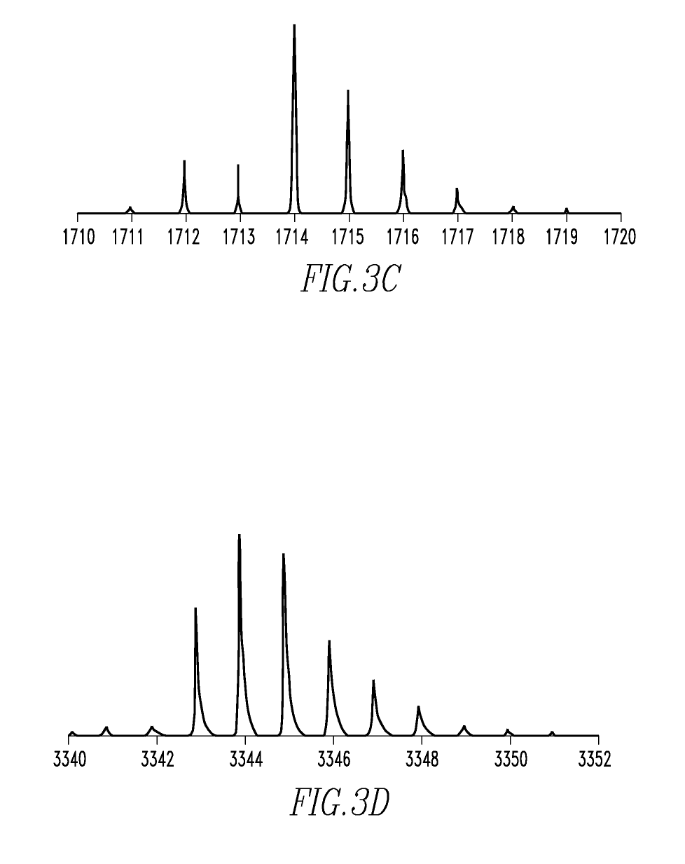

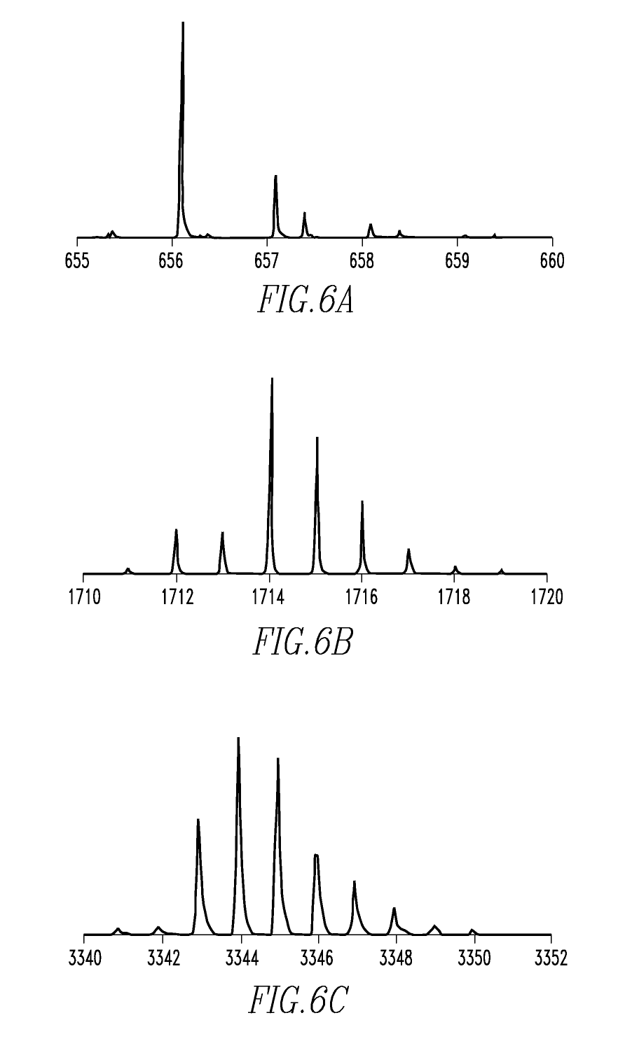

FIGS. 6A-6C show the results of processing of the data of FIG. 3 according to the table shown in FIG. 5. The processing reduced the number of data points from an initial number of 723,766 to 142,687, i.e., to about 20%.

In FIG. 5, the amount of deleted data is set to increase in going to higher masses. The method consisting of causing the amount of deleted data to increase in steps in going to higher masses is possible. In practice it is possible, of course, to maintain the quality of mass spectral data in a region of interest by means of a sufficient number of data points by selecting this region of interest and setting the data compression ratio in that region smaller than the data compression ratios in its adjacent regions.

### Embodiment 2

A TOF mass spectrometer of embodiment 2 of the present invention is identical in fundamental structure with the spectrometer of embodiment 1. In embodiment 1, data points about flight times which are at regular intervals of time are combined into one. Data points may also be integrated and/or compressed such that m/z values are at regular intervals of the squares of flight times.

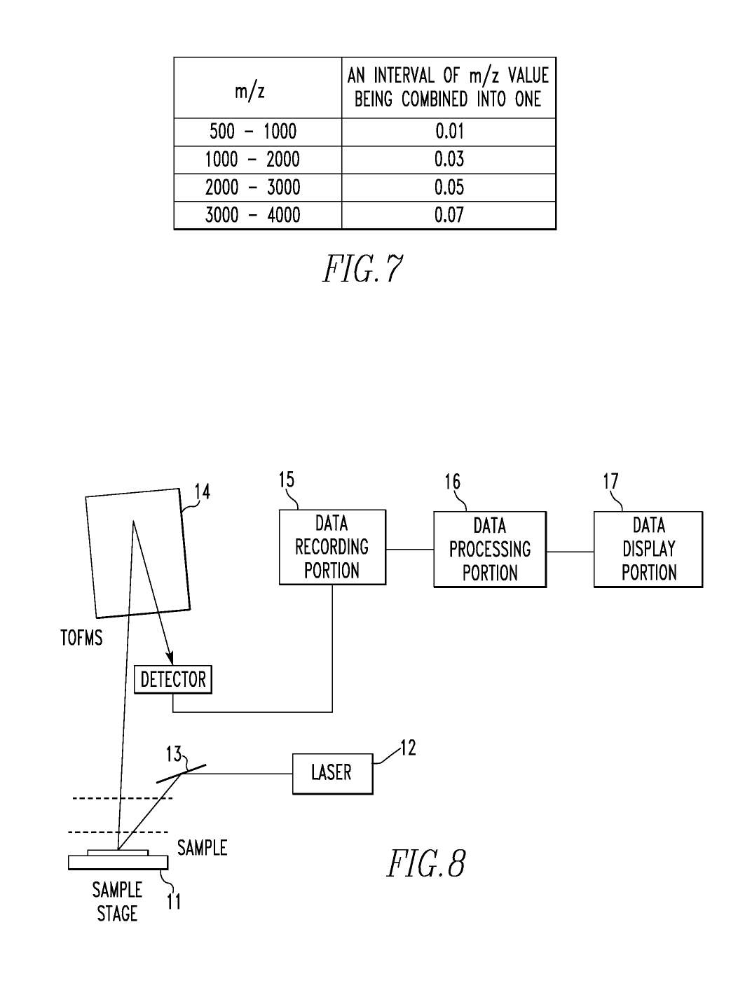

In this case, data points derived at regular intervals of time are combined together into data points which are regularly spaced apart in terms of m/z value. For this purpose, m/z regions and intervals at which combination is made are previously specified and organized into a table (FIG. 7). As a result, the number of data points which was 723,766 at first was reduced to 117,619. That is, a compression to about 16% was achieved.

### Embodiment 3

A TOF mass spectrometer according to embodiment 3 is identical in fundamental structure with embodiments 1 and 2. In embodiments 1 and 2, data points that are regularly spaced apart in terms of flight time or m/z value are combined. The number of data points can also be reduced by applying this technique to data derived from a time-of-flight mass spectrometer coupled to a liquid or gas chromatograph.

### Embodiment 4

It is possible to reduce the number of data points obtained by an imaging mass spectrometry (IMS) technique utilizing MALDI (matrix-assisted laser desorption/ionization) or SIMS (secondary-ion mass spectrometry) by applying the present invention to these data points.

FIG. 8 shows the whole structure of a MALDI mass spectrometer having imaging capability, the spectrometer being used in the present invention. The spectrometer includes a sample stage 11 used to vary the position of the sample and the laser beam position on the sample. The surface of the sample on the sample stage 11 is illuminated with a sequence of pulses of laser light generated from a laser 12 via a laser optical system 13 including a mirror and lenses. The area of the sample illuminated with the laser light is on the order of tens of micrometers in width.

Ions of the sample generated from the sample surface in response to the laser illumination are accelerated by an ion acceleration section made up of a mesh, and are passed through a time-of-flight mass analyzer 14, whereby the ions are mass-analyzed. The sample ions which have been mass-analyzed arrive successively at a detector from the lightest ions. The ions are converted into an electrical signal and sent to a data recording portion 15. An ion signal recorded on the data recording portion 15 is processed by a data processing portion 16. The signal is displayed as a mass spectrum on a data display portion 17.

This measurement is performed repeatedly while driving the sample stage 11. Mass spectra of a two-dimensional area are obtained in succession while varying the laser light position on the sample surface.

Generally, a mass spectrometer having imaging capability has:
(1) a sample drive mechanism capable of driving and scanning the ionized portion of a sample in two dimensions;
(2) a data recording portion which ionizes the sample while driving the sample drive mechanism and which obtains and records mass spectra of ions generated from the sample surface together with two-dimensional positional information;
(3) a data processing portion for imaging ion peaks having a desired mass-to-charge ratio selected from among mass spectra recorded in the data recording portion based on the two-dimensional positional information on the sample; and (4) a data display portion for displaying mass images created by the data processing portion.

Since huge amounts of mass spectral data obtained by repetitive measurements are often handled, a quite large amount of data is produced. The data is effectively compressed in the same way as in embodiments 1-3.

The present invention can be widely applied to data processing methods employed in time-of-flight mass spectrometers.

Having thus described my invention with the detail and particularity required by the Patent Laws, what is desired protected by Letters Patent is set forth in the following claims.

The invention claimed is

1. A time-of-flight mass spectrometer comprising:
an ion source for ionizing a sample;
a time-of-flight mass analyzer for causing generated ions to travel and mass-separating the ions according to their mass-to-charge ratio;
a detector for detecting the ions mass-separated by the mass analyzer according to their mass-to-charge ratio and outputting an electrical signal;
a digitizer for converting the electrical signal outputted from the detector into digital form; and
a processing unit to which digital data from the digitizer is supplied,
wherein said processing unit has (1) data compression means for reducing the number of data points of the digital data such that m/z regions partitioned by given flight times or given m/z are set to have different numbers of data points and (2) storage means in which the digital data whose number of data points has been reduced by the data compression means are stored over a long term.

2. A time-of-flight mass spectrometer as set forth in claim 1, wherein said data compression means reduces the number of data points by taking an average of flight times, m/z values, or ion intensity values between preset numbers of data points.

3. A time-of-flight mass spectrometer as set forth in claim 1, wherein the number of data points of the digital data that is set to different values for the m/z regions partitioned by the given flight times or given m/z is set to larger values with increasing m/z value of measured ion peak.

4. A time-of-flight mass spectrometer as set forth in claim 1, wherein the number of data points of the digital data that is set to different values for the m/z regions partitioned by the given flight times or given m/z is set to a smaller value for a preset m/z region as compared with its adjacent m/z regions.

5. A time-of-flight mass spectrometer as set forth in claim 1, wherein a chromatograph is coupled to said ion source, and wherein the number of data points of the digital data obtained by measuring the sample isolated chromatographically is reduced.

6. A time-of-flight mass spectrometer as set forth in claim 1, wherein said ion source is a MALDI or SIMS ion source, and wherein the number of data points obtained using imaging mass spectrometry is reduced.

7. A data compression method for use by a time-of-flight mass spectrometer producing a mass spectrum including a greatly increased number of digital data points, said method comprising the steps of
reducing the number of data points of said digital data such that m/z regions partitioned by given flight times or given m/z are set to have different numbers of data points; and
then storing the digital data whose number of data points has been reduced.

8. A data compression method as set forth in claim 7, wherein during said step of reducing the number of data points of the digital data, the number of the data points is reduced by taking an average of flight times, m/z values, or ion intensity values between preset numbers of data points.

9. A data compression method as set forth in claim 7, wherein during said step of reducing the number of data points of the digital data, the m/z regions partitioned by the given flight times or given m/z are set to have different numbers of data points such that the number of data points in any one m/z region increases with increasing m/z value of measured ion peak.

10. A data compression method as set forth in claim 7, wherein during said step of reducing the number of points of the digital data, the number of data points of the digital data that is set to different values for the m/z regions partitioned by the given flight times or given m/z is set to a smaller value for a preset m/z region as compared with its adjacent m/z regions.

11. A data compression method as set forth in claim 7, wherein a chromatograph is coupled to said time-of-flight mass spectrometer, and wherein the number of data points of digital data obtained by measuring the sample isolated chromatographically is reduced.

12. A data compression method as set forth in claim 7, wherein said TOF mass spectrometer uses a MALDI or SIMS ion source, and wherein the number of data points obtained using imaging mass spectrometry is reduced.
